(19) United States
(12) Patent Application Publication
(10) Pub. No.: US 2008/0261552 A1
(43) Pub. Date: Oct. 23, 2008

(54) LOW VOLTAGE IQ DUAL MIXER

(75) Inventor: Yuan-Hung Chung, Hsinchu County (TW)

Correspondence Address: THOMAS, KAYDEN, HORSTEMEYER & RISLEY, LLP, 600 GALLERIA PARKWAY, S.E., STE 1500, ATLANTA, GA, 30339-5994, US

(73) Assignee: MEDIATEK INC., Hsin-Chu (TW)

(21) Appl. No.: 11/737,333

(22) Filed: Apr. 19, 2007

(51) Int. Cl. H03D 7/14

(52) U.S. Cl. 455/333

(57) ABSTRACT

An IQ dual mixer for use in radio transmitters and receivers, comprising an in-phase (I) local oscillator transistor pair, a quadrature-phase (Q) local oscillator transistor pair, and a first radio frequency (RF) transistor. The I local oscillator transistor pair is operably coupled to receive an I local oscillator signal and connected in series with a first load pair to output an I product signal. The Q local oscillator transistor pair is operably coupled to receive a Q local oscillator signal and connected in series with a second load pair to output a Q product signal. The first RF transistor has an input terminal coupled to receive a first RF signal. The first RF transistor is coupled in anti-series with each transistor of the I and Q local oscillator transistor pairs.

### BACKGROUND OF THE INVENTION

1. Field of the Invention

The invention generally relates to radio frequency (RF) technologies and in particular to IQ dual mixers used with RF technologies.

2. Description of the Related Art

Wireless communication systems enable one wireless device to transmit data to at least another wireless device through a wireless transmission medium. A wireless communication system may be constructed, and hence operate, in accordance with one or more standards including IEEE 802.11a, 802.11b, Bluetooth, global system for mobile communication (GSM), code division multiple access (CDMA), wireless application protocol (WAP), and variations thereon.

As is well known, wireless communication systems use radio frequencies for transmission, requiring an RF transmitter and an RF receiver. Generally speaking, a conventional RF transmitter has at least a modulator, a local oscillator, mixers, a power amplifier and an antenna. The inter-operation of these components modulates data signals into RF signals. An RF receiver generally has an antenna, a low noise amplifier, mixers, a local oscillator, a filter and a demodulator to recapture the data signals from the RF signals.

Mixers within RF transmitters and RF receivers determine quality of the communication system. The factors in mixer performance include conversion gain, local oscillator (LO) power, linearity, noise figure, port-to-port isolation, voltage supply, and current (or power) consumption.

A fundamental choice in mixer design is whether to use an active or passive mixer. Passive mixers (operating transistors in the linear region) provide increased dynamic range, moderate conversion loss and excellent intermodulation performance at the expense of LO power. Unfortunately, large LO drives are difficult to implement in a low-voltage environment, resulting in increased power consumption, and dictate increased LO-RF/LO-IF isolation, such that low-voltage/low-power integrated circuit (IC) design favors active mixers for which reduced LO drives are acceptable.

A high quality active mixer illustrated in FIG. 1 is known as a Gilbert mixer. When used for down-conversion, the Gilbert mixer multiplies a differential RF signal (consisting of RF+ and RF− antiphase signals) by a LO signal (consisting of LO+ and LO− antiphase signals) and generates a corresponding intermediate frequency (IF) signal (consisting of IF+ and IF− antiphase signals). The output may be a baseband signal if a zero-IF topology is utilized. The Gilbert mixer in FIG. 1 has six transistors Q1-Q6 together with load resistors RLN and RLP and a current source Is, which implies at least another transistor. Transistors Q1-Q4 connected to LO+ and LO− input terminals belong to a LO core, receiving a LO signal. Transistors Q5-Q6 connected to RF+ and RF− input terminals belong to an RF core, receiving a differential RF signal. The Gilbert mixer is a compact, efficient approach to combining a differential amplifier with a phase reversing switch mixer. The RF signal modulates the currents in transistors Q5-Q6, causing them to act as a differential amplifier. Normally, transistors Q1-Q4 are effectively switched, where a high input causes them to switch on and a low input causes them to switch off. Transistors Q1-Q4 can reverse the phase or polarity of the current from transistors Q5-Q6, depending on whether they are on or off. Two load resistors RLN and RLP translate the switched, modulated currents therethrough into an IF signal output as IF+ and IF− signals from IF+ and IF− output terminals respectively.

As shown in FIG. 1, the Gilbert mixer has a stack of three transistors and a load resistor between the voltage rails. Each of the three transistors requires a specific voltage bias to sustain operation. For low supply voltage applications, most of the supply voltage may be preempted by the stacked transistors, such that the conversion gain and headroom capacity, both substantially decided by the residual voltage across the load resistor, may be insufficient.

### BRIEF SUMMARY OF THE INVENTION

An embodiment of the invention provides an IQ dual mixer for use in radio transmitters and receivers, comprising an in-phase (I) local oscillator transistor pair, a quadrature-phase (Q) local oscillator transistor pair, and a first radio frequency (RF) transistor. The I local oscillator transistor pair is operably coupled to receive an I local oscillator signal and connected in series with a first load pair to output an I product signal. The Q local oscillator transistor pair is operably coupled to receive a Q local oscillator signal and connected in series with a second load pair to output a Q product signal. The first RF transistor has an input terminal coupled to receive a first RF signal. The first RF transistor is coupled in anti-series with each transistor of the I and Q local oscillator transistor pairs.

An embodiment of the invention also provides an IQ dual mixer, comprising a LO core, a RF core and a load core. The LO core has LO transistors receiving I and Q LO signals. The RF core has at least one RF transistor receiving an RF signal. The load core is connected with the LO core to output I and Q product signals according to the I and Q LO signals and the RF signal. The RF transistor is coupled in anti-series with each of the LO transistors.

An embodiment of the invention also provides a method for signal up-conversion or down-conversion. A first radio frequency signal is received using a first radio frequency (RF) transistor. An I local oscillator signal is processed to continuously alternate switching. One step enables one transistor of an I local oscillator transistor pair while the other transistor of the I local oscillator transistor pair is disabled. The other step enables the other transistor of the I local oscillator transistor pair while the one transistor of the I local oscillator transistor pair is disabled. The first RF transistor is coupled in anti-series with each transistor of the I oscillator transistor pair. A Q local oscillator signal is processed to continuously alternate switching between two other steps. One enables one transistor of a Q local oscillator transistor pair while the other transistor of the Q local oscillator transistor pair is disabled. The other step enables the other transistor of the Q local oscillator transistor pair while the one transistor of the Q local oscillator transistor pair is disabled. The first RF transistor is coupled in anti-series with each transistor of the Q oscillator transistor pair. An I product signal across two output terminals of the I local oscillator transistor pair is output while a Q product signal across two output terminals of the Q local oscillator transistor pair is output.

A detailed description is given in the following embodiments with reference to the accompanying drawings.

### BRIEF DESCRIPTION OF DRAWINGS

The invention can be more fully understood by reading the subsequent detailed description and examples with references made to the accompanying drawings, wherein:

FIG. 1 shows a conventional Gilbert mixer;

FIGS. 2 and 3 show two low voltage, balanced IQ dual mixers according to embodiments of the invention;

FIGS. 4 and 5 show two low voltage, unbalanced IQ dual mixers according to embodiments of the invention; and

FIGS. 6 and 7 teaches two possible configurations with a frequency-related impedance between a LO pair and an RF transistor.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

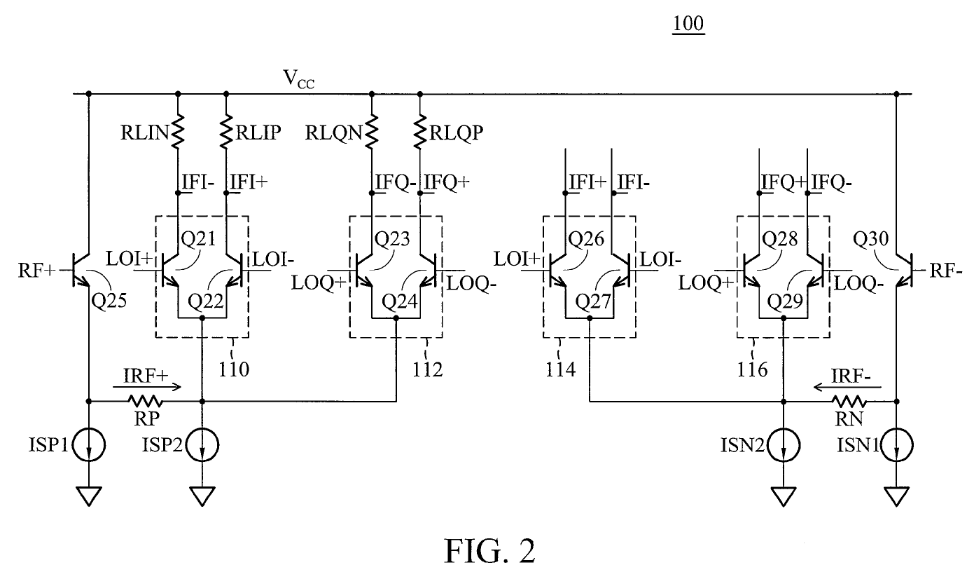

FIG. 2 is a schematic diagram of a low voltage, balanced IQ dual mixer 100 according to embodiments of the invention. IQ dual mixer 100 multiplies an RF signal, a differential signal represented by RF+ and RF− antiphase signals, by a LO in-phase (I) signal, represented by LOI+ and LOI− antiphase singals, to generate an IFI signal. IQ dual mixer 100 also multiplies the RF signal by a LO quadrature-phase (Q) signal, represented by LOQ+ and LOQ− antiphase singals, to generate an IFQ signal. In other words, IQ dual mixer 100 alone extracts and processes I and Q portions of the RF signal to generate corresponding IFI and IFQ signals.

IQ dual mixer 100 has 4 basic portions: a LO core, a RF core, a load core, and bias circuit. The LO core has 2 I LO transistor pairs 110 and 114, and 2 Q LO transistor pairs 112 and 116. Transistor Q21, belonging to I LO transistor pair 110 and receiving LOI+ signal, is connected in series with resistor RLIN. Transistor Q22, receiving LOI− signal, is the other transistor in I LO transistor pair 110 and is connected in series with resistor RLIP. Transistors Q21 and Q22 form an emitter-coupled transistor pair. Similar to I LO transistor pair 110, transistors Q23 and Q24 form Q LO transistor pair 112, receive LOQ+ and LOQ− signals, and are connected in series with resistors RLQN and RLQP respectively. Each transistor in I LO transistor pair 110 and Q LO transistor pair 112 is coupled in anti-series with transistor Q25 through resistor RP. The phrase, “coupled in anti-series”, means that the connection between two devices is through two terminals with the same characteristic. For example, in FIG. 2, transistors Q25 and Q21 are coupled in anti-series because the emitter of one BJT is coupled to the emitter of the other. Alternative anti-series connections for BJTs include base-to-base and collector-to-collector connections. For diodes, cathode-to-cathode connection or anode-to-anode connection are two possible candidates for anti-series connection.

I LO transistor pair 114, Q LO transistor pair 116 and transistor Q30 are coupled similar to I LO transistor pair 110, Q LO transistor pair 112 and transistor Q25, but with different signal polarity. Transistor Q30 and Q25 both belong to the RF core, receiving RF− and RF+ signals respectively. Even though transistors Q26 and Q21 receive the same LOI+ signal, transistor Q26 is connected in series with RLIP while transistor Q21 is connected in series with RLIN. The connection difference between transistors Q26 and Q21 can also be applied to transistors Q27 and Q22, transistors Q28 and Q23, and transistors Q29 and Q24. In other words, I LO transistor pairs 110 and 114 are coupled to create a balanced mixing action and Q LO transistor pairs 112 and 116 are coupled to create another.

The load core has two load pairs: resistors RLIN and RLIP, and resistors RLQN and RLQP. Resistors RLIN and RLIP are the loading for I LO transistor pairs 110 and 114, and provide IF terminals for outputting IFI− and IFI+ signals. Resistors RLQN and RLQP are the loading for Q LO transistor pairs 112 and 116, and provide IF terminals for outputting IFQ− and IFQ+ signals.

A bias circuit in FIG. 2 has four current sources (ISP1, ISP2, ISN1 and ISN2) and resistors (RP and RN). The bias circuit provides proper operating bias conditions to the transistors in IQ dual mixer 100 and may be implemented in any number of ways. Furthermore, resistors RP and RN can affect the conversion gain of IQ dual mixer 100.

With the introduction of LOI+, LOI−, LOQ+ and LOQ− signals, the transistors in the LO core alternatively switch on and off, where, as known in the art, LOI+ signal differs from LOQ+ signal by 90 degree phase. Either transistors Q21 and Q26 are on and transistors Q22 and Q27 off, or vice versa. Either transistors Q23 and Q28 are on and transistors Q24 and Q29 off, or vice versa.

The RF+ signal modulates the current through transistor Q25 while RF− signal modulates the current through transistor Q30. With the left portion of FIG. 2 as an example, modulated current IRF+, as blocked and redirected by constant current source ISP1, passes resistor RP, and splits into two parts. One part passes either resistor RLIN or RLIP, based on which transistor in I LO transistor pair 110 is on at that moment, to vary the voltage on the IF output terminals. Similarly, the other part of modulated current IRF+ passes either resistor RLQN or RLQP based upon which transistor in Q LO transistor pair 112 is on at that moment. As shown in FIG. 2, modulated current IRF− through transistor Q30 responds similarly to modulated current IRF+, and explanation thereof is omitted herefrom. At any moment, one part of modulated current IRF+ passes one of resistors RLIN or RLIP while one part of modulated current IRF− passes the other. Similarly, one part of modulated current IRF+ passes one of resistors RLQN or RLQP while one part of modulated current IRF− passes the other. Transistors Q25 and Q30, and resistors RP, RN, RLIN and RLIP together act as a differential amplifier for the RF signal and the currents through resistors RLIN and RLIP are alternatively exchanged based on LOI signal to produce the same sum-and-difference output signal as a conventional Gilbert mixer. Transistors Q25 and Q30, and resistors RP, RN, RLQN and RLQP together act as another differential amplifier for the RF signal and the currents through resistors RLQN and RLQP are alternatively exchanged based upon LOQ signal. The two differential amplifiers share a common RF core and a common bias circuit. Compared to two fully-separated I and Q mixers, the configuration in FIG. 2 reduces required silicon area and current consumption.

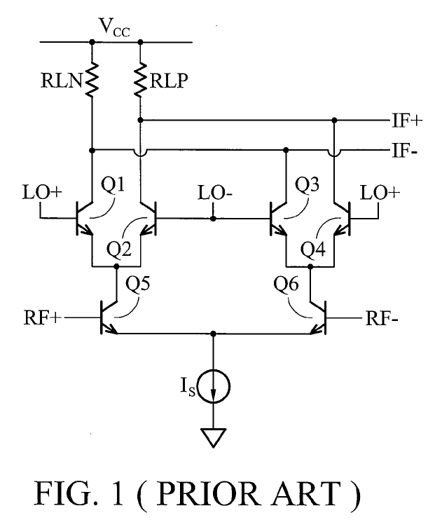

As shown in FIG. 2, the IQ dual mixer, comprising two stacked transistors with a load resistor between the voltage rails, where the LO core contributes one transistor and the bias circuit the other, compared with the Gilbert mixer of FIG. 1, having three stacked transistors to be biased, is more suitable for low voltage applications.

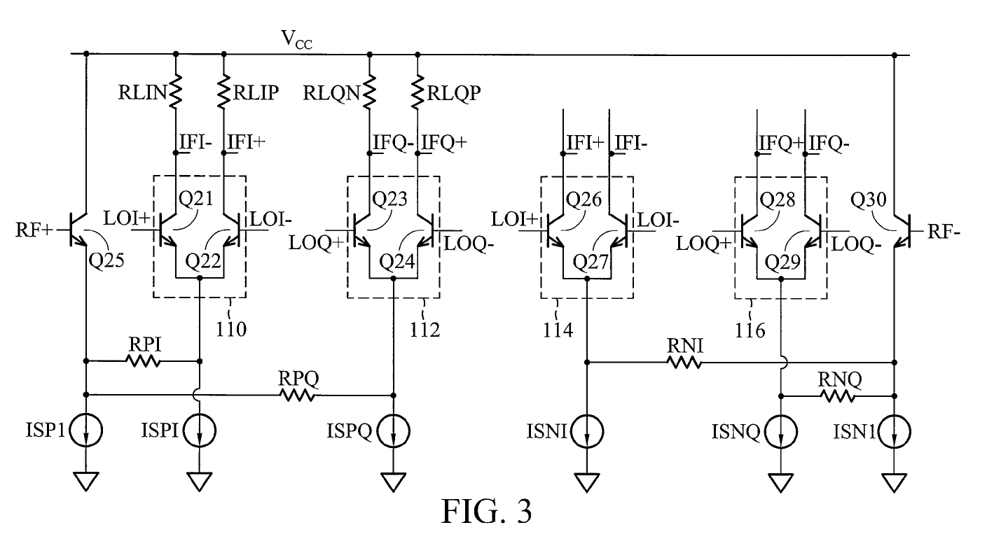

FIG. 3 is another schematic diagram of a low voltage, balanced IQ dual mixer, differing from that of FIG. 2 in the bias circuit. The bias circuit in FIG. 3 has six current sources ISP1, ISPI, ISPQ, ISN1, ISNI and ISNQ, and four resistors RPI, RPQ, RNI and RNQ. Current sources ISPI, ISPQ, ISNI and ISNQ provide operation points for I LO transistor pair 110, Q LO transistor pair 112, I LO transistor pair 114 and Q LO transistor pair 116, respectively. Resistors RPI and RPQ provide the RF+ signal two signal paths all the way to I LO transistor pair 110 and Q LO transistor pair 112, such that modulated current from transistor Q25 is separated. Similarly, resistors RNI and RNQ provide the RF− signal two signal paths to I LO transistor pair 114 and Q LO transistor pair 116, respectively.

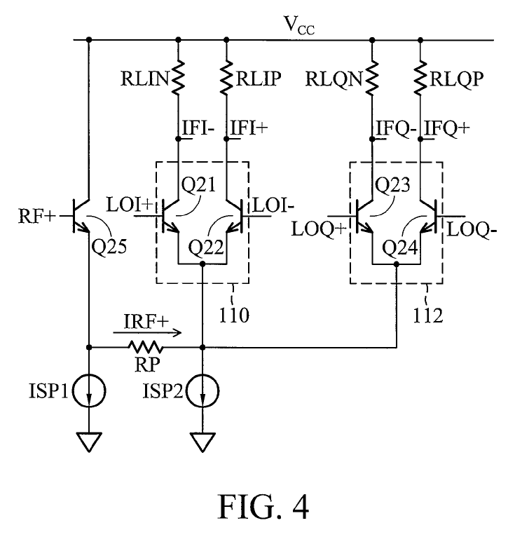

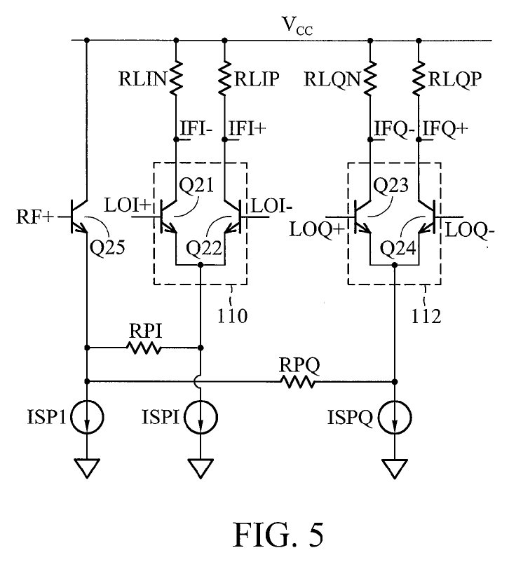

Alternative embodiments of the invention may utilize unbalanced IQ dual mixers, rather than the balanced IQ dual mixers shown in FIGS. 2 and 3. FIGS. 4 and 5 exemplify two unbalanced IQ dual mixers according to embodiments of the invention. FIG. 4 lacks the right portion of FIG. 2, which balances the left portion of FIG. 2 by introducing signals with polarities opposite to those from the left portion. While having only one RF input terminal, the mixer in FIG. 4 still generates IFI and IFQ signals and, thus, is an unbalanced IQ dual mixer. FIG. 5 shows another unbalanced IQ dual mixer having only the left portion of FIG. 3.

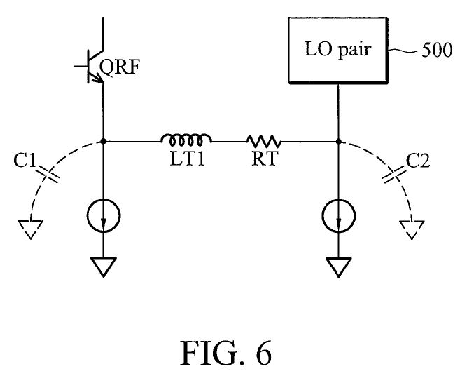

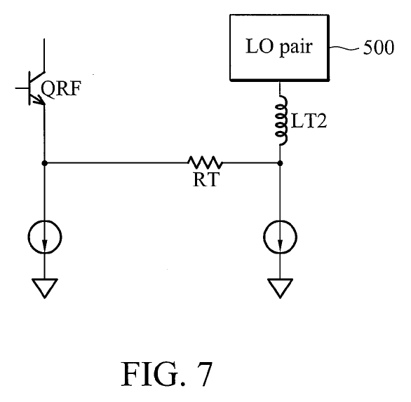

As mentioned, the resistor connecting a LO transistor pair and one RF transistor in a RF core provides a signal path, impedance of which affects the overall conversion gain of a mixer. The impedance of this signal path can be modified by introducing inductors or capacitors therein to obtain a desired frequency response. For example, FIG. 6 introduces inductor LT1 connected in series with resistor RT between transistor QRF and LO pair 500, such that the combination of inductor LT1 and resistor RT has a frequency-related impedance. Inductor LT1 interacts with parasitic capacitors C1 and C2 to form a low pass filter which substantially allows the RF signal to pass while depressing other signals with higher frequencies. Using a similar concept, FIG. 7 introduces inductor LT2 connected between resistor RT and LO pair 500 to have a better frequency response for RF signal. The frequency-related impedance in FIG. 6 or 7 can be applied to a corresponding part(s) in any one of the IQ dual mixers disclosed in FIGS. 2-5.

Each of the disclosed IQ dual mixers can be fabricated in a chip by BICMOS process. While the transistors in the figures are drawn as bipolar junction transistors, they are not intended to limit the scope of the invention. Other transistors, such as MOSFET transistors, can be used alone or in combination with other transistors to embody the invention under the scope of the invention.

While the invention has been described by way of examples and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A IQ dual mixer for use in radio transmitters and receivers, comprising:
an in-phase (I) local oscillator transistor pair operably coupled to receive an I local oscillator signal and connected in series with a first load pair to output an I product signal;
a quadrature-phase (Q) local oscillator transistor pair operably coupled to receive a Q local oscillator signal and connected in series with a second load pair to output a Q product signal; and
a first radio frequency (RF) transistor having an input terminal coupled to receive a first RF signal;
wherein the first RF transistor is coupled in anti-series with each transistor of the I and Q local oscillator transistor pairs.

2. The IQ dual mixer of claim 1, wherein the I local oscillator transistor pair is a first I local oscillator transistor pair, the Q local oscillator transistor pair is a first Q local oscillator transistor pair, and the IQ dual mixer further comprises:
a second I local oscillator transistor pair operably coupled to receive the I local oscillator signal and connected in series with the first load pair to output the I product signal;
a second Q local oscillator transistor pair operably coupled to receive Q local oscillator signal and connected in series with the second load pair to output the Q product signal; and
a second radio frequency (RF) transistor having an input terminal coupled to receive a second RF signal;
wherein the second RF transistor is coupled in anti-series with each transistor of the second I and Q local oscillator transistor pairs; and
wherein the first and second RF signals are originated for a differential RF input signal, the first and second I local oscillator transistor pairs are coupled to create a balanced mixing action, the first and second Q local oscillator transistor pairs are coupled to create another balanced mixing action.

3. The IQ dual mixer of claim 1, wherein the I and Q local oscillator transistor pairs share a common connection point, and the IQ dual mixer further comprises a first resistor coupled between the first radio frequency (RF) transistor and the I local oscillator transistor pair.

4. The IQ dual mixer of claim 3, wherein the IQ dual mixer further comprises a first inductor coupled in series with the first resistor and between the first radio frequency (RF) transistor and the I local oscillator transistor pair.

5. The IQ dual mixer of claim 1, further comprising a biasing circuit biasing the first radio frequency (RF) transistor, the I local oscillator transistor pair and the Q local oscillator transistor pair.

6. The IQ dual mixer of claim 1, further comprising
a first resistor coupled between the I local oscillator transistor pair and the first radio frequency (RF) transistor; and
a second resistor coupled between the Q local oscillator transistor pair and the first radio frequency (RF) transistor.

7. The IQ dual mixer of claim 6, further comprising:
a first inductor coupled in series with the first resistor and between the first radio frequency (RF) transistor and the I local oscillator transistor pair; and
a second inductor coupled in series with the second resistor and between the first radio frequency (RF) transistor and the Q local oscillator transistor pair.

8. The IQ dual mixer of claim 1, wherein the first radio frequency (RF) transistor, the I local oscillator transistor pair and the Q local oscillator transistor pair are MOS transistors.

9. The IQ dual mixer of claim 1, wherein the first radio frequency (RF) transistor, the I local oscillator transistor pair and the Q local oscillator transistor pair are bipolar junction transistors.

10. A method for signal up-conversion or down-conversion, comprising:
receiving a first radio frequency signal using a first radio frequency (RF) transistor;
processing an I local oscillator signal to continuously alternate switching between:
enabling one transistor of an I local oscillator transistor pair while the other transistor of the I local oscillator transistor pair is disabled; and
enabling the other transistor of the I local oscillator transistor pair while the one transistor of the I local oscillator transistor pair is disabled;
wherein the first RF transistor is coupled in anti-series with each transistor of the I oscillator transistor pair;
processing a Q local oscillator signal to continuously alternate switching between:
enabling one transistor of a Q local oscillator transistor pair while the other transistor of the Q local oscillator transistor pair is disabled; and
enabling the other transistor of the Q local oscillator transistor pair while the one transistor of the Q local oscillator transistor pair is disabled;
wherein the first RF transistor is coupled in anti-series with each transistor of the Q oscillator transistor pair;
outputting an I product signal across two output terminals of the I local oscillator transistor pair; and
outputting a Q product signal across two output terminals of the Q local oscillator transistor pair.

11. The method of claim 10, wherein the I local oscillator transistor pair is a first I local oscillator transistor pair, the Q local oscillator transistor pair is a first Q local oscillator transistor pair, and the method further comprises
receiving a second radio frequency signal using a second radio frequency (RF) transistor;
processing I local oscillator signal to continuously alternate switching between:
enabling one transistor of a second I local oscillator transistor pair while the other transistor of the second I local oscillator transistor pair is disabled; and
enabling the other transistor of the second I local oscillator transistor pair while the one transistor of the second I local oscillator transistor pair is disabled;
wherein the second RF transistor is coupled in anti-series with each transistor of the second I oscillator transistor pair; and
processing Q local oscillator signal to continuously alternate switching between:
enabling one transistor of a second Q local oscillator transistor pair while the other transistor of the second Q local oscillator transistor pair is disabled; and
enabling the other transistor of the second Q local oscillator transistor pair while the one transistor of the second Q local oscillator transistor pair is disabled;
wherein the second RF transistor is coupled in anti-series with each transistor of the second Q oscillator transistor pair;
wherein the first and second RF signals are originated from a differential RF input signal, the first and second I local oscillator transistor pairs are coupled to create a balanced mixing action, and the first and second Q local oscillator transistor pair are coupled to create another balanced mixing action.

12. The method of claim 11, further comprising:
biasing the first radio frequency (RF) transistor, and the first and second I local oscillator transistor pairs; and
biasing the second radio frequency (RF) transistor, and the first and second Q local oscillator transistor pairs.

13. An IQ dual mixer, comprising:
a LO core with LO transistors to receiving I and Q LO signals;
a RF core having at least one RF transistor to receive an RF signal; and
a load core connected with the LO core to output I and Q product signals according to the I and Q LO signals and the RF signal;
wherein the RF transistor is coupled in anti-series with each of the LO transistors.

14. The IQ dual mixer of claim 13, further comprising a biasing circuit for biasing the LO transistors and the RF transistor.

15. The IQ dual mixer of claim 13, further comprising a resistor coupled between the RF transistor and the LO core.

16. The IQ dual mixer of claim 15, further comprising an inductor coupled between the RF transistor and the LO core.

17. The IQ dual mixer of claim 13, wherein the LO core comprises an I LO transistor pair receiving the I LO signal and a Q LO transistor pair receiving the Q LO signal, and the IQ dual mixer further comprises:
a first resistor coupled between the RF transistor and the I LO core pair; and
a second resistor coupled between the RF transistor and the Q LO core pair.
